(19) United States
(12) Patent Application Publication
(10) Pub. No.: US 2026/0165081 A1
(43) Pub. Date: Jun. 11, 2026

(54) HIGH-PRECISION XY POSITIONING SYSTEM FOR SEMICONDUCTOR PROCESSING EQUIPMENT

(71) Applicant: ETEL S.A., Môtiers (CH)

(72) Inventors: Marta Dragon-Louiset, Saint-Blaise (CH); Sébastien Soares, Arçon (FR); Raphaël Louiset, Saint-Blaise (CH)

(21) Appl. No.: 19/178,932

(22) Filed: Apr. 15, 2025

(30) Foreign Application Priority Data
May 2, 2024 (EP) 24173913.5

(51) Int. Cl. H10P 72/50; H10P 72/00

(52) U.S. Cl. CPC H10P 72/53; H10P 72/0608

(57) ABSTRACT

A system for positioning a payload, including a base, linear guides fixed to the base and extending along an X-direction of a coordinate system and an X-stage including a transversal beam extending along a Y-direction of the coordinate system. The transversal beam includes a frame of a first material and a guiding surface. A Y-stage with a carriage is adapted to receive the payload and at least one air-bearing connected to the carriage and including a pad surface facing the guiding surface of the transversal beam. Ducts exhaust pressurized air from the pad surface to create an air film between the pad guiding surfaces. The guiding surface includes a ceramic coating and a layer of second material between the coating and the frame. The second material has a coefficient of thermal expansion lower than that of the first material and higher than that of the ceramic coating.

### CROSS REFERENCE TO RELATED APPLICATIONS

This application claims benefit to European Patent Application No. EP 24173913.5, filed on May 2, 2024, which is hereby incorporated by reference herein.

### FIELD

The present invention relates to positioning systems for the semiconductor industry and to high-precision XY positioning systems for accurate positioning of a payload of semiconductor processing equipment.

### BACKGROUND

Multi-axis positioning systems generally comprise mechanical bearings arranged to slide along rails to position a stage in an X-Y coordinate system associated to the system. Mechanical bearings have several limitations which prevent the positioning system to address the ever-tightening requirements from the semiconductor industry. These limitations include in particular:
micron-level parasitic movements or vibrations due to the irregularities on the surface of the rails of the positioning machine along which the mechanical bearings are intended to slide;
friction occurring between rolling elements of the mechanical bearings and the rails which causes a hysteresis effect to the slides when they come to a stop, whereby positioning the stage in the X-Y coordinates system with an accuracy lower than 100 nm is not possible;
wear generating particles which may become airborne and pollute surfaces, and
lubrication such as oil or grease, used to limit friction, which also generates volatile particles which may pollute sensitive parts.

Various solutions have been proposed to overcome these limitations. U.S. Pat. Nos. 5,040,431 and 4,916,340, for example, disclose an XY positioning system comprising air bearings slidably mounted against a ceramic beam, such as Silicon Carbide or alumina. Such construction has the advantage of providing both tight flatness tolerance, down to the micron-level and low rugosity down to 0.2 microns.

Yet, ceramic beams have the inconvenience of requiring complex and heavy installations for machining the beam, due to their hardness, thereby increasing the production cost of these systems. In addition, the ceramic, in particular alumina, has a low thermal conductivity. Accordingly, the ceramic beam does not dissipate well the heat generated by the motors. This negatively affects the precision of the system.

### SUMMARY

In an embodiment, the present disclosure provides an XY positioning system for positioning a payload of semiconductor processing equipment, the system comprising a fixed base, two stationary linear guides fixed to the base and extending along an X-direction of a cartesian coordinate system and an X-stage comprising a transversal beam extending along a Y-direction of the cartesian coordinate system between the two stationary linear guides and two carriages connected to respective ends of the transversal beam and slidably engaged with respective stationary linear guides of the two stationary linear guides. The transversal beam comprises a frame of a first material and a guiding surface. The XY positioning system further comprises a Y-stage comprising a carriage adapted to fixedly receive the payload and at least one air-bearing connected to the carriage and including a pad surface facing the guiding surface of the transversal beam. The at least one air-bearing comprises ducts configured to exhaust pressurized air from the pad surface to create an air film of a predetermined thickness between the pad surface and the guiding surface. The XY positioning system further comprises at least one X-linear motor arranged to move the X-stage along the X-direction and a Y-linear motor arranged to move the Y-stage along the Y-direction. The guiding surface comprises a ceramic coating and a layer of a second material between the ceramic coating and the frame of the transversal beam. The second material has a coefficient of thermal expansion lower than a coefficient of thermal expansion of the first material and higher than a coefficient of thermal expansion of the ceramic coating.

### BRIEF DESCRIPTION OF THE DRAWINGS

Subject matter of the present disclosure will be described in even greater detail below based on the exemplary figures. All features described and/or illustrated herein can be used alone or combined in different combinations. The features and advantages of various embodiments will become apparent by reading the following detailed description with reference to the attached drawings, which illustrate the following:

FIG. 1 shows a perspective view of a high-precision XY positioning system for positioning a payload of semiconductor processing equipment, according to an embodiment of the present disclosure;

FIG. 2 shows an enlarged view of a Y-stage of the positioning system of FIG. 1, taken in the detail circle of FIG. 1;

FIG. 3 shows a cross-sectional view of the Y-stage of FIG. 2, in a plane perpendicular to a Y-axis;

FIG. 4 shows an enlarged view of FIG. 3 at an interface between a guiding surface of a transversal beam and an air-bearing;

FIG. 4a is an enlarged view of the air-bearing against the guiding surface of FIG. 4 at a level of air-bearing ducts; and

FIG. 4b is an enlarged view of a portion of the guiding surface of the transversal beam of FIG. 4, and

FIG. 5 shows a perspective view of the transversal beam of an X-stage of the positioning system of FIG. 1.

### DETAILED DESCRIPTION

In an embodiment, the present disclosure provides a high-precision XY positioning system for positioning a payload of semiconductor processing equipment, such as a silicon wafer handling stage, which overcomes the above limitations.

The foregoing limitations are overcome, at least in part, by an XY positioning system for highly accurate positioning of a payload of semiconductor processing equipment, comprising a fixed base, two stationary linear guides fixed to the base and extending along the X-direction of a cartesian coordinates system, an X-stage, an X-linear motor arranged to move the X-stage along the X-direction, a Y-stage, and a Y-linear motor arranged to move the Y-stage along the Y-direction. The X-stage comprises a transversal beam extending along the Y-direction of the cartesian coordinates system between the two stationary linear guides and two carriages connected to respective ends of the transversal beam and slidably engaged with respective stationary linear guides. The transversal beam comprises a frame of a first material and a guiding surface. The Y-stage comprises a carriage adapted to fixedly receive the payload of the semiconductor processing equipment and at least one air-bearing connected to the carriage. The air-bearing comprises a pad surface facing the guiding surface of the transversal beam. The air-bearing comprises one or more ducts for exhausting pressurized air from the pad surface to create an air film of a predetermined thickness between the guiding surface of the transversal beam and the pad surface.

This guiding surface comprises a ceramic coating and a layer of a second material between the ceramic coating and the frame of the transversal beam. The second material has a coefficient of thermal expansion lower than the coefficient of thermal expansion of the first material of the frame of the transversal beam and higher than the coefficient of thermal expansion of the ceramic coating.

In an embodiment, the Y-linear motor comprises a magnetic track connected to the transversal beam and a coil unit fitted inside the magnetic track. The latter is arranged to extend between two longitudinal sides of the transversal beam along the Y-direction.

In an embodiment, the flatness of the ceramic coating over an area defined by the length and width of the guiding surface is comprised within a range from one to two micrometres.

In an embodiment, the thickness of the air film, when the positioning system is operating, is comprised between three and six micrometres.

In an embodiment, the ceramic coating is made of alumina (Al₂O₃).

In an embodiment, the second material is nickel or a nickel alloy.

In an embodiment, the thickness of the ceramic coating is selected within a range from 200 micrometres to one millimetre.

In an embodiment, the thickness of the second material is selected within a range from 30 micrometres to 200 micrometres, preferably between 40 and 60 micrometres.

In an embodiment, the ceramic coating is impregnated with a resin, for example a phenolic resin.

In an embodiment, the frame of the transversal beam is in aluminum.

In an embodiment, the second material and the ceramic coating are applied respectively on the frame of the transversal beam and on said second material by an Atmospheric Plasma Spraying (APS) process.

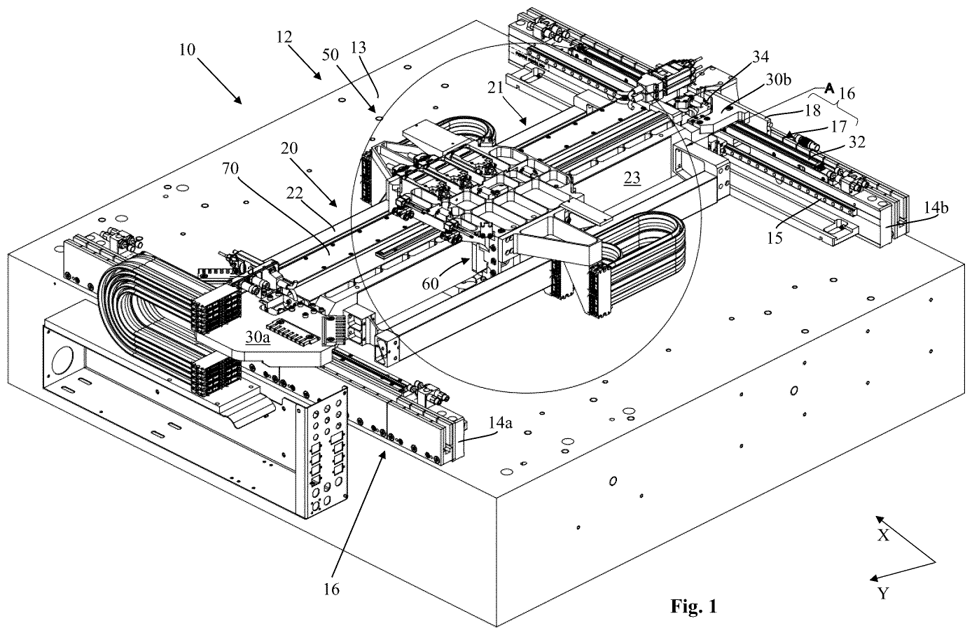

With reference to FIG. 1, the high-precision XY positioning system 10 comprises a

conventional granite base 12 having a flat and smooth top surface 13. Two stationary linear guides 14a, 14b are fixed to the top surface 13 of the granite base 12 near two opposite ends thereof. These two linear guides 14a, 14b are arranged parallel to each other along an X-direction of a cartesian XY coordinate system to drive an X-stage 20 in both ways along this direction.

The X-stage 20 comprises a transversal beam 21 which extends along the Y-direction of the cartesian coordinates system. Two X-carriages 30a, 30b are connected to respective ends of the transversal beam 21 and are slidably engaged with respective stationary linear guides 14a, 14b. More particularly, each X-carriage 30a, 30b comprises a mechanical bearing mounted on a rail 15 fixed along a side of each stationary linear guides 14a, 14b.

The XY positioning system 10 further comprises two X-linear motors 16 each comprising a magnetic track 17 extending along respective linear guides 14a, 14b and a glider 18, comprising a set of coils, fitted in the magnetic track and connected to respective carriages 30a, 30b. The transversal beam 21 is thus moved in the X-direction when the coils of the gliders 18 of the motors 16 are energised. The XY positioning system 10 also comprises two linear encoders for positioning the X-stage 20 along the X-direction. Each linear encoder comprises an encoder scale 32 arranged on an upper side of respective linear guides 14a, 14b and an optical reader 34 mounted on respective carriages 30a, 30b to face respective encoder scale 32.

In an embodiment, the precision XY positioning system can comprise only one X-linear motor to drive one end of the transversal beam along the X-direction while the other end of the transversal beam is merely slidably coupled to a linear guide.

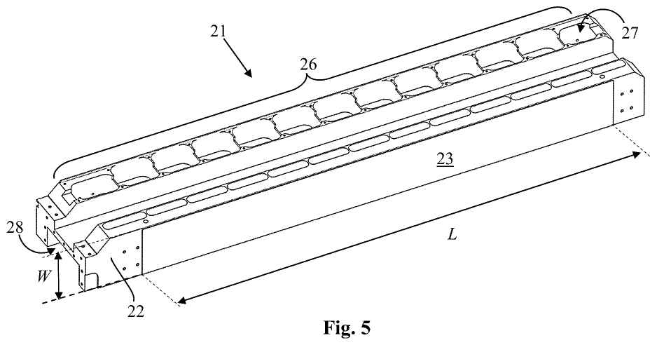

With reference to FIGS. 3 and 5, the beam 21 has a substantially H-shaped cross-section orthogonal to the beam length. This H-shaped cross-section is constant along most of the entire length of the beam. In a preferred embodiment, the beam 21 is in aluminium or in an aluminium alloy: it advantageously comprises a series of adjacent apertures 27 arranged along its entire length and extending from the upper to the lower part of the beam in order to, on the one hand, decrease the weight while keeping high rigidity of the beam and, on the other hand, increase the thermal exchange surface to efficiently dissipate the heat generated by a Y-linear motor 40 arranged on the beam to drive a Y-stage 50 in the Y-direction along the beam.

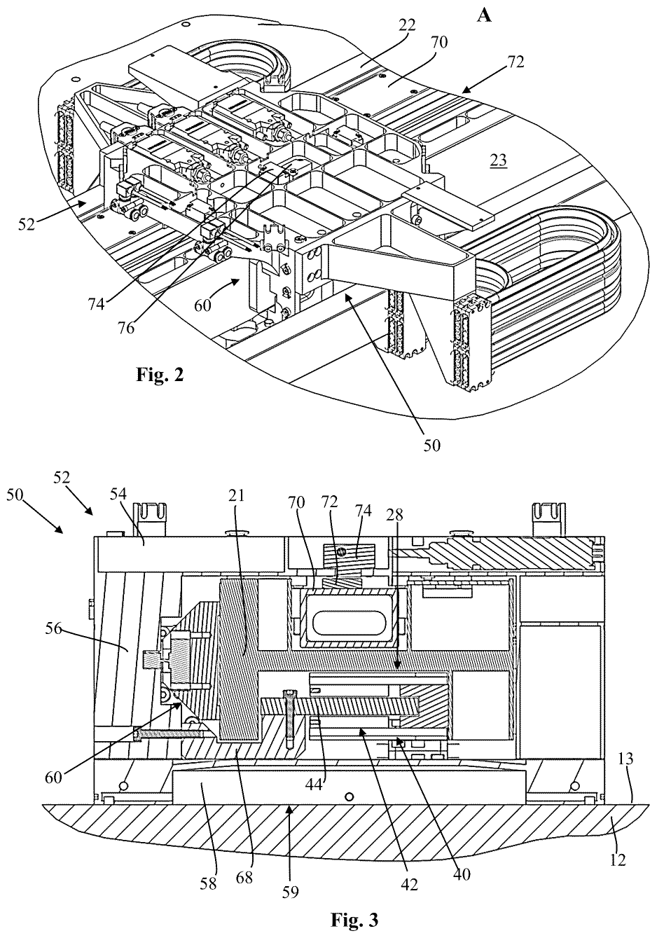

With reference to FIGS. 2 and 3, the Y-stage 50 comprises a Y-carriage 52 comprising an upper part 54 configured to fixedly receive a payload of a semiconductor processing equipment. The lower part of the transversal beam 21 comprises a longitudinal space 28 of a rectangular parallelepiped shape along which is fixed the magnetic track 42 of the Y linear motor 40 as shown in FIG. 3. A glider 44, comprising a set of coils, is fitted inside the motor magnetic track 42 and is connected to the carriage 52 of the Y-stage 50 by a connecting bracket 68 to drive the carriage 52 along the transversal beam. This connecting bracket 68 has an L-shaped portion extending below a part of the transversal beam 21 to connect a part of the glider 44 to a side wall 56 of the Y-carriage 52.

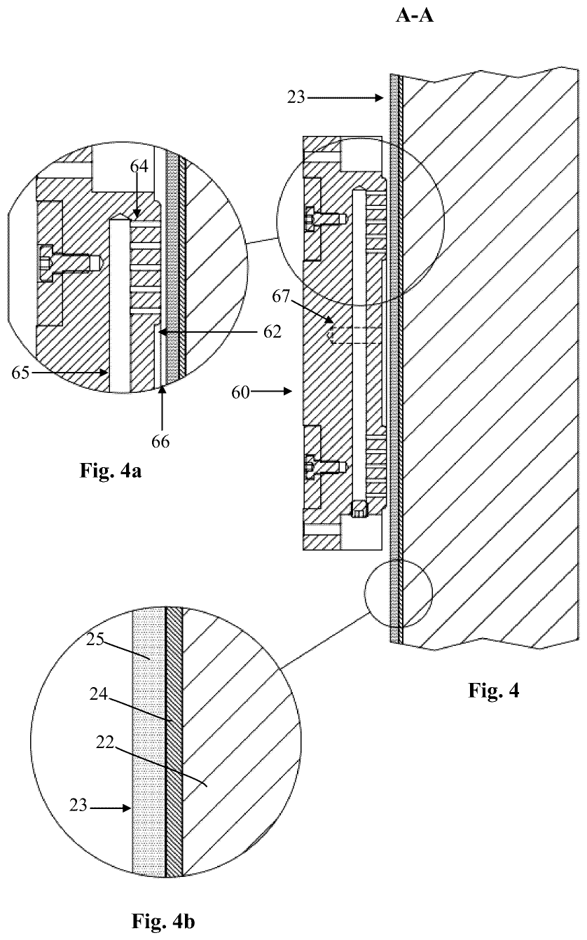

The Y-stage 50 also comprises an air-bearing 60 attached to the same side wall 56 of the Y-carriage 52 such that a flat pad surface 62 of the air-bearing 60 faces a guiding surface 23 of the transversal beam 21 as shown in FIGS. 4 and 4a. In the depicted embodiment, another air-bearing 58 is mounted on the lower part of the Y-carriage 52 to create an air gap between a pad surface 59 of the air-bearing and the top surface 13 of the granite base 12.

The XY positioning system 10 further comprises a metrological hollow beam 70 with a rectangular transversal cross-section. The metrological beam is arranged to extend along a longitudinal rectangular parallelepiped-shaped space located in an upper portion of the transversal beam 21, without any contact with the latter as illustrated in FIG. 3. Both ends of the metrological beam 70 are connected to respective carriages 30a, 30b as shown in FIG. 1. The metrological beam 70 is preferably in alumina (Al₂O₃), in silicon carbide or in another material with a low coefficient of thermal expansion.

The XY positioning system 10 comprises a linear encoder for positioning the Y-stage 50 along the transversal beam 21. The encoder comprises an encoder scale 72 mounted along an upper side of the metrological beam 70. In a preferred embodiment, the encoder scale 72 is of the type of 1D+scale which features an incremental track along the Y-direction as well as additional track that provides the information required for compensation in the perpendicular direction and for angular correction. A first and a second optical reader 74, 76 are thus mounted on the Y-carriage 52, as shown in FIG. 2, to read respectively the incremental track and the additional track respectively.

Referring to FIGS. 4 and 4a, the air-bearing 60 comprises ducts 64 for exhausting pressurized air from the pad surface 62. In a preferred embodiment, the air-bearing further comprises a vacuum channel 67 in communication with vacuum means to suck air from a central part of the pad surface 62. The force of pressurized air impinging upon the guiding surface 23 is sufficient to lift the air-bearing from the guiding surface. The use of both pressured air and vacuum means enables to create an equilibrium condition in which the gas supply volume equals the gas leakage volume to create an air film 66 with laminar flow of a predetermined thickness between the pad surface 62 and the guiding surface 23. Air-bearings configured to operate with pressurized air and a vacuum system are well known in the art and described for example in New Way, “Air Bearing Application and Design Guide”, Rev. E, January 2006, https://www.newwayairbearings.com/sites/default/files/new_way_application_and_design_guide _%20Rev_E_2006-01-18.pdf.

This air film thickness is of the utmost importance since the lower it is, the higher the stiffness of the air-bearing is, and thereby improves the accuracy of the XY positioning system. The flatness of the guiding surface must thus be as low as possible to reduce the air film thickness as much as possible. As a general rule of thumb, the flatness of the guiding surface 23 corresponds approximately to one third of the air film thickness. To make that surface as flat as possible, the guiding surface 23 comprises a ceramic coating 25 with a flatness comprised between one and two micrometers over an area defined by the length L and width W of the guiding surface 23 as illustrated in FIG. 5. This flatness therefore translates into an air film 66 having a thickness comprised between three and six micrometres when the XY positioning system is operating.

In order to achieve such flatness, the transversal beam 21 is first milled out of a bock of aluminium alloy, of grade 6082 for example, to obtain at least one lateral side of the beam with a flatness below 15 microns, preferably down to approximately 10 microns. A sanding process is then applied only to the area defined by the length L and width W of the guiding surface (FIG. 5) in order to provide a surface of a predefined roughness to ensure an optimal adhesion of a first layer 24 (FIGS. 4 and 4b) of nickel or of a nickel alloy. The application of this first layer is performed by an Atmospheric Plasma Spraying (APS) process. The parameters of this process are set to obtain a layer thickness comprised between 30 micrometres and 200 micrometres and preferably between 40 and 60 micrometres. The size of the grain of nickel or nickel alloy should be preferably comprised in the range from 15 to 90 μm.

Once the first layer 24 is applied, a ceramic coating 25 is applied on this first layer using for example the same APS process and by setting the process parameters to obtain a ceramic coating thickness comprised between 200 micrometres and one millimetre and preferably between 500 and 700 micrometres. The ceramic is preferably alumina (Al₂O₃) but other types of ceramic can be used. The size of the grain of Al₂O₃ should be preferably comprised in the range from 5 to 45 μm.

The role of the first layer is to avoid any cracking of the ceramic coating 25. Indeed, alumina has a low coefficient of thermal expansion and may crack under the thermal expansion of the transversal beam 21 induced by the heating generated the Y-linear motor 40. The nickel or nickel alloy has an intermediate coefficient of thermal expansion with respect to the coefficient of thermal expansion of aluminium and alumina. The first layer of nickel or nickel alloy therefore partially absorbs the expansion of the aluminum beam thereby reducing mechanical stresses on the ceramic coating to avoid any cracking of the ceramic.

In an embodiment, the first layer of nickel or nickel alloy of the guiding surface can be replaced by a layer of another material whose coefficient of thermal expansion is lower than the one of aluminium and higher than the one of alumina or of other types of ceramic.

The ceramic coating 25 is then ground and then lapped down to a flatness comprised between one and two micrometers. More particularly, the ceramic coating can first be ground down to a flatness comprised within the range from 5 to 10 microns and then lapped to its final flatness. The lapping can be carried out with silicon carbide or diamond grains, the size of which is comprised within the range from 15 to 45 microns.

In an embodiment, the ceramic coating can be impregnated with a resin, for example a phenolic resin. This resin advantageously fills in the porosities between ceramic grains. The resin can be sprayed onto the ceramic coating or applied with a paintbrush, preferably before the lapping.

In an embodiment, the XY positioning system comprises a transversal beam with two longitudinal opposite guiding surfaces provided with the ceramic coating and the intermediate layer obtained by the above description. In this case, the Y-carriage comprises two air-bearings mounted to face respective guiding surfaces of the transversal beam. This design has the advantage of providing symmetry in the distribution of weight while promoting bilateral guidance. Additionally, this design can make use of air-bearings comprising only pressurized air, because the vacuum is not needed to create the preload force of the air-bearings.

While embodiments of the present disclosure have been illustrated and described in detail in the drawings and foregoing description, such illustration and description are to be considered illustrative or exemplary and not restrictive. It will be understood that changes and modifications can be made by those of ordinary skill within the scope of the appended claims. For example, the mechanical bearings of the X-stage can be replaced by air bearing mounted at both ends of the transversal beam to face a guiding surface disposed along a side of the stationary linear guides extending in the X-direction. Such guiding surface can comprise an intermediate layer and a ceramic coating with the same properties as those described in relation to the guiding surface of the transversal beam.

While subject matter of the present disclosure has been illustrated and described in detail in the drawings and foregoing description, such illustration and description are to be considered illustrative or exemplary and not restrictive. Any statement made herein characterizing the invention is also to be considered illustrative or exemplary and not restrictive as the invention is defined by the claims. It will be understood that changes and modifications may be made, by those of ordinary skill in the art, within the scope of the following claims, which may include any combination of features from different embodiments described above.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

### LIST OF REFERENCE SIGNS

XY positioning system 10
Base 12
Top surface 13
Stationary linear guides 14a, 14b
Rails 15
X-linear motor 16
Magnetic track 17
Glider 18
X-stage 20
Transversal beam 21
Frame 22
Guiding surface 23
Nickel layer 24
Ceramic coating 25
Heat exchanger 26
Apertures 27
Lower groove 28
X-carriages 30a, 30b
Linear encoder
Encoder scale 32
Optical reader 34
Y-linear motor 40
Magnetic track 42
Glider 44
Y-stage 50
Y-carriage 52
Upper side 54
Sides wall 56
Air bearing 58
Pad surface 59
Air-bearings 60
Pad surface 62
Ducts 64
Pressurized air channel 65
Air film 66
Vacuum channel 67
Connecting bracket 68
Metrological beam 70
Linear encoder
Encoder scale 72
First optical reader 74
Second optical reader 76

1. An XY positioning system for positioning a payload of semiconductor processing equipment, the system comprising:
a fixed base;
two stationary linear guides fixed to the base and extending along an X-direction of a cartesian coordinate system;
an X-stage comprising a transversal beam extending along a Y-direction of the cartesian coordinate system between the two stationary linear guides and two carriages connected to respective ends of the transversal beam and slidably engaged with respective stationary linear guides of the two stationary linear guides, wherein the transversal beam comprises a frame of a first material and a guiding surface;
a Y-stage comprising a carriage adapted to fixedly receive the payload and at least one air-bearing connected to the carriage and including a pad surface facing the guiding surface of the transversal beam, wherein the at least one air-bearing comprises ducts configured to exhaust pressurized air from the pad surface to create an air film of a predetermined thickness between the pad surface and the guiding surface;
at least one X-linear motor arranged to move the X-stage along the X-direction; and
a Y-linear motor arranged to move the Y-stage along the Y-direction,
wherein the guiding surface comprises a ceramic coating and a layer of a second material between the ceramic coating and the frame of the transversal beam, and
wherein the second material has a coefficient of thermal expansion lower than a coefficient of thermal expansion of the first material and higher than a coefficient of thermal expansion of the ceramic coating.

2. The XY positioning system according to claim 1, wherein the Y-linear motor comprises a magnetic track connected to the transversal beam and a glider fitted inside the magnetic track, and wherein the magnetic track extends between two longitudinal sides of the transversal beam along the Y-direction.

3. The XY positioning system according to claim 1, wherein a flatness of the ceramic coating over an area defined by a length and a width of the guiding surface is within a range of from one to two micrometres.

4. The XY positioning system according to claim 1, wherein the predetermined thickness of the air film between the pad surface and the guiding surface is between three and six micrometres.

5. The XY positioning system according to claim 1, wherein the ceramic coating is made of alumina.

6. The XY positioning system according to claim 1, wherein the second material is nickel or a nickel alloy.

7. The XY positioning system according to claim 1, wherein a thickness of the ceramic coating is within a range of from 200 micrometres to one millimetre.

8. The XY positioning system according to claim 1, wherein a thickness of the second material is within a range of from 30 micrometres to 200 micrometres.

9. The XY positioning system according to claim 1, wherein the ceramic coating is impregnated with a resin.

10. The XY positioning system according to claim 1, wherein the frame of the transversal beam comprises aluminum or an aluminum alloy.

11. The XY positioning system according to claim 1, wherein the second material and the ceramic coating are applied respectively on the frame of the transversal beam and on the second material by an Atmospheric Plasma Spraying process.

12. The XY positioning system according to claim 8, wherein the thickness of the second material is between 40 and 60 micrometres.

13. The XY positioning system according to claim 9, wherein the ceramic coating is impregnated with a phenolic resin.
